(19) United States
(12) Patent Application Publication
(10) Pub. No.: US 2007/0151705 A1
(43) Pub. Date: Jul. 5, 2007

(54) Heat dissipating clamp for dissipating heat of chips in an electrical device

(76) Inventor: Rita Y. Kwan, Taipei (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/585,151

(22) Filed: Oct. 24, 2006

(30) Foreign Application Priority Data
Dec. 30, 2005 (TW) 094147519

(51) Int. Cl. H05K 7/20

(52) U.S. Cl. 165/80.2; 361/714

(57) ABSTRACT

A heat dissipating clamp for an electrical device with a chip group has a station bracket and a holding bracket. The station bracket and the holding bracket are combined together as clamp and both are made of metal with a high dissipating efficiency. The station bracket has an inner surface and a recess. The recess is formed in the inner surface of the station bracket and has multiple holes. The holes separately formed through the station bracket. The electrical device is clamped between the station bracket and the holding bracket. The chip group abuts against the station bracket and the holding bracket. Accordingly, the heat generated by the chip group will be transmitted to the heat dissipating clamp and be dissipated efficiently, so that the chip group can keep at certain working temperature.

### BACKGROUND OF THE INVENTION

1. Field of the Invention

The present invention relates to a clamp, and more particularly to a heat dissipating clamp that has an excellent heat dissipating efficiency to cool chips in an electrical device efficiently.

2. Description of Related Art

Current computers' electrical device such as a memory card or a central processing unit, is developed to have a small size and a higher operative efficiency. However, the chips with the higher operative efficiency will generate great heat during processing. If the temperatures of the chips are too high, the operative efficiency of the chips will reduce and chips may be burned out.

To prevent situation discussed above, a conventional heat sink is provided to dissipate the heat of the chips. The heat sink can keep the chips at a certain temperature range so that the chips are able to work as normally.

A conventional heat sink has a base and multiple fins. The base has a top and a bottom. The fins are mounted on the top of the base.

The bottom of the base is attached to a chip. Heat dissipating cream is arranged between the base and the chip. The heat generating from the chip will be transmitted to the base through the heat dissipating cream so that the temperature of the chip may be efficiently cooled down.

After a period of use, the heat dissipating cream may dry out so that the heat transmission efficiency from the chip to the base is reduced. The heat generating by the chip is not efficiently dissipated.

Furthermore, current computer's design is developed toward to a small, thin, short and light trend. In order to fit a compact size of the computer, the heat sink has to be reduced in size. With the reduction in size of the convention heat sink, the heat dissipating effect of the heat sink are also decreased.

To overcome the shortcomings, the present invention provides a heat dissipating clamp to obviate or mitigate the aforementioned problems. SUMMARY OF THE INVENTION

The main objective of the invention is to provide a heat dissipating clamp that has an excellent heat dissipating efficiency and a compact size.

The heat dissipating clamp for an electrical device with a chip group has a station bracket and a holding bracket. The station bracket and the holding bracket are combined together as clamp and both are made of metal with a high dissipating efficiency. The station bracket has an inner surface and a recess. The recess is formed in the inner surface of the station bracket and has holes. The holes separately formed through the station bracket. The electrical device is clamped between the station bracket and the holding bracket. The chip group abuts against the station bracket and the holding bracket. The chip group abuts against the station bracket and the holding bracket. Accordingly, the heat generated by the chip group will be transmitted to the heat dissipating clamp and be dissipated efficiently, so that the chip group can keep at certain working temperature. In addition, part of heat generated by the chip can be dissipated from the holes in the station bracket, and the heat dissipating effect of the clamp is improved.

Furthermore, the station bracket and the holding bracket are slice-sharp so that the heat dissipating clamp can be set into any narrowed size computer. The computer with the heat dissipating clamp inside can has better heat dissipating efficiency.

Other objectives, advantages and novel features of the invention-will become more apparent from the following detailed description when taken in conjunction with the accompanying drawings.

### BRIEF DESCRIPTION OF THE DRAWINGS

FIG. 1 is a perspective view of a first embodiment of a heat dissipating clamp in accordance with the present invention when an electrical device is clamped by the heat dissipating clamp;

FIG. 2 is an exploded perspective view of the first embodiment of the heat dissipating clamp in FIG. 1;

FIG. 3 is a perspective view of the first embodiment of a station bracket in FIG. 1;

FIG. 4 is a perspective view of a second embodiment of the heat dissipating clamp in accordance with the present invention when the electrical device is clamped by the heat dissipating clamp;

FIG. 5 is a perspective view of a third embodiment of the heat dissipating clamp in accordance with the present invention when the electrical device is clamped by the heat dissipating clamp;

FIG. 6 is a perspective view of a fourth embodiment of the heat dissipating clamp in accordance with the present invention when the electrical device is clamped by the heat dissipating clamp;

FIG. 7 is a perspective view of a fifth embodiment of the heat dissipating clamp in accordance with the present invention when the electrical device is clamped by the heat dissipating clamp; and

FIG. 8 is a perspective view of a sixth embodiment of the heat dissipating clamp in accordance with the present invention when the electrical device is clamped by the heat dissipating clamp.

### DETAILED DESCRIPTION OF THE PREFERRED EMBODIMENT

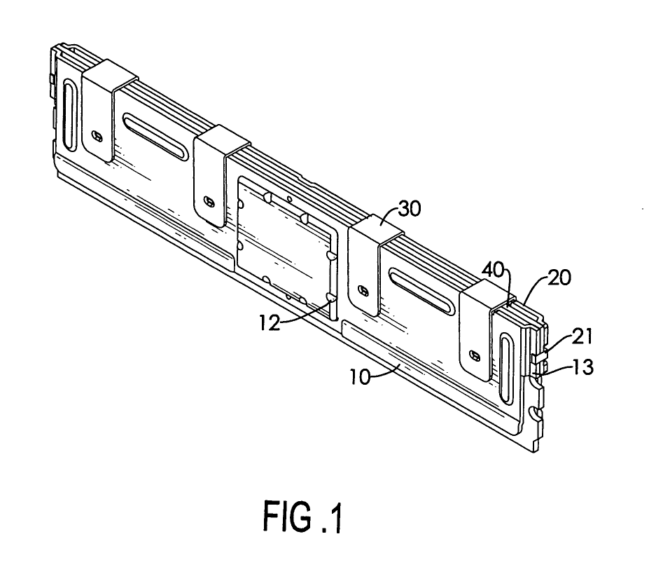

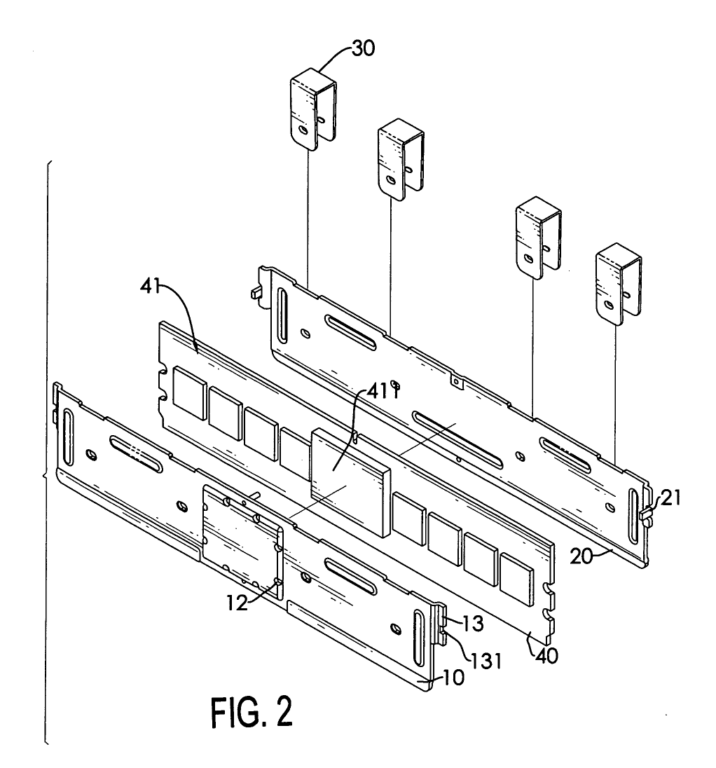

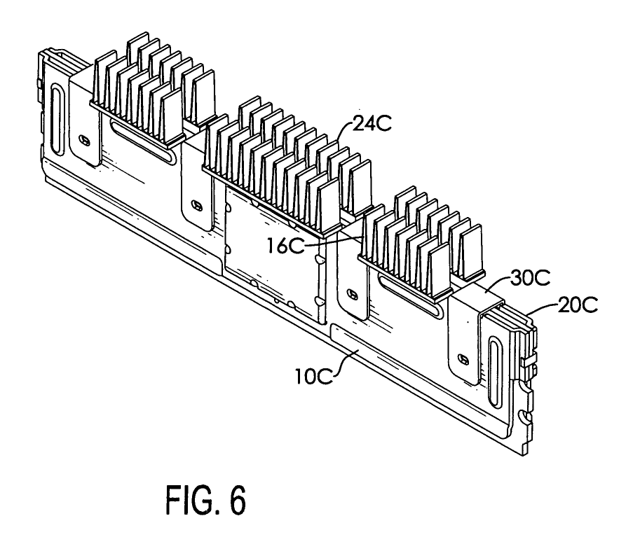

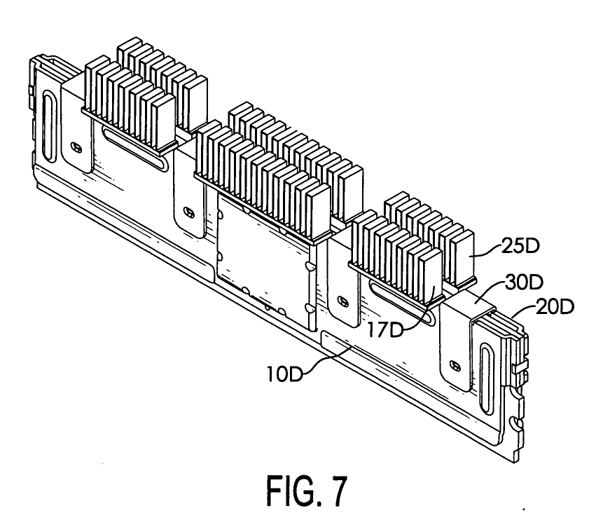

With reference to FIGS. 1, 2, 4, 5, 6, 7 and 8, a heat dissipating clamp in accordance with the present invention for an electrical device (40) has a station bracket (10, 10A, 10B, 10C, 10D, 10E), a holding bracket (20, 20A, 20B, 20C, 20D, 20E), mounted clips (30, 30A, 30B, 30C, 30D, 30E) and optional fins (14A, 15B, 16C, 17D, 18E, 22A, 23B, 24C, 25D, 26E).

The electrical device (40) may be a memory card and has two sides and a chip group (41). The chip group (41) is mounted at two sides of the electrical device (40) and has one chip (411) that generates heat during processing.

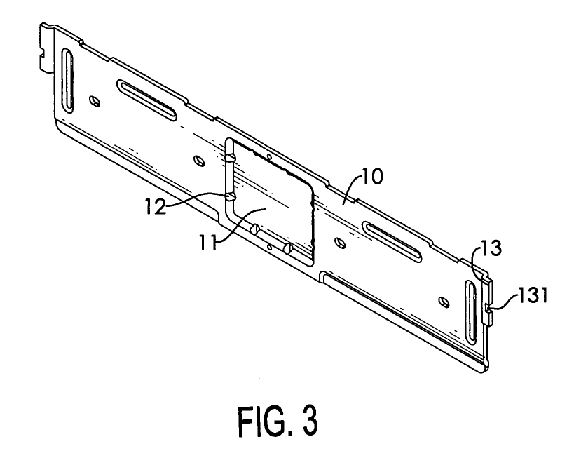

With further reference to FIG. 3, the station bracket (10, 10A, 10B, 10C, 10D, 10E) is made of metal with a high dissipating efficiency and has two ends, an inner surface, a top, a recess (11) and two optional ears (13). The recess (11) is formed in the inner surface of the station bracket (10, 10A, 10B, 10C, 10D, 10E) and has an edge and holes (12). The holes (12) are separately formed through the edge of the recess (12). Each ear (13) is formed on and extended out of one end of the station bracket (10, 10A, 10B, 10C, 10D, 10E) and has a cutout (131). The cutout (131) is formed at the edge of the ear (13) of the station bracket (10, 10A, 10B, 10C, 10D, 10E).

The holding bracket (20, 20A, 20B, 20C, 20D, 20E) is made of metal with a high dissipating efficiency and has a top, two ends, two optional extensions (21) and an inner surface. Each extension (21) is formed on and extended out of one end of the holding bracket (20, 20A, 20B, 20C, 20D, 20E) and is received into a corresponding one of the cutouts (131) in the station bracket (10, 10A, 10B, 10C, 10D, 10E).

The mounted clips (30, 30A, 30B, 30C, 30D, 30E) are separately mounted on the top of the station bracket (10, 10A, 10B, 10C, 10D, 10E) and the top of the holding bracket (20, 20A, 20B, 20C, 20D, 20E) to combine the station bracket (10, 10A, 10B, 10C, 10D, 10E) and the top of the holding bracket (20, 20A, 20B, 20C, 20D, 20E) together as a clamp. Each mounted clip (30, 30A, 30B, 30C, 30D, 30E) is U-shaped.

The fins (14A, 15B, 16C, 17D, 18E, 22A, 23B, 24C, 25D, 26E ) may be extension-shaped, plate-shaped, a triangular-plate-shaped or U-plate-shaped.

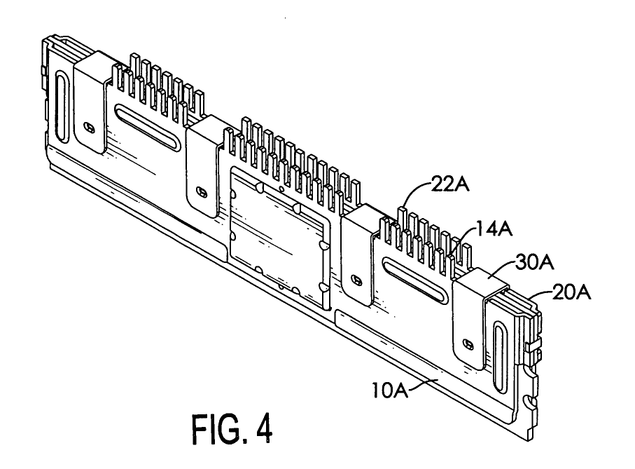

With further reference to FIG. 4, the fins (14A, 22A) are separately formed on the top of the station bracket (10A) and the holding bracket (20A) and between the mounted clips (30, 30A, 30B, 30C, 30D, 30E).

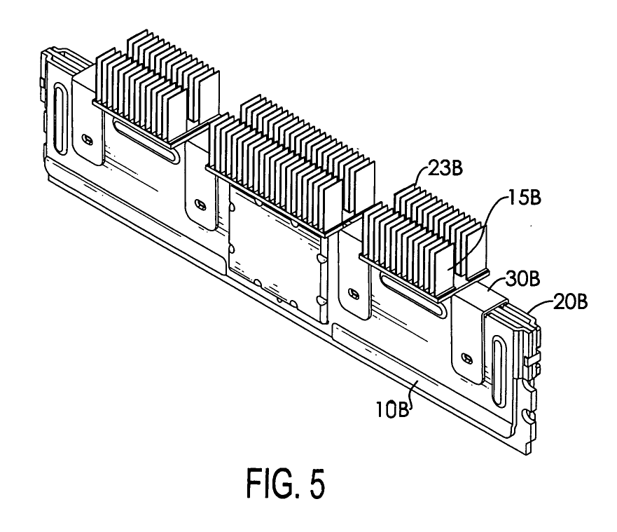

With further reference to FIGS. 5, 6, 7 and 8, the fins (15B, 16C, 17D, 18E, 23B, 24C, 25D, 26E) are separately mounted on the tops of the station bracket (10B,10C, 10D, 10E) and the holding bracket (20B, 20C, 20D, 20E) and between the mounted clips (30, 30A, 30B, 30C, 30D, 30E). To attach the fins (15B, 16C, 17D, 18E, 23B, 24C, 25D, 26E) onto the brackets (10B, 10C, 10D, 10E, 20B, 20C, 20D, 20E) may use a welding or any possible process.

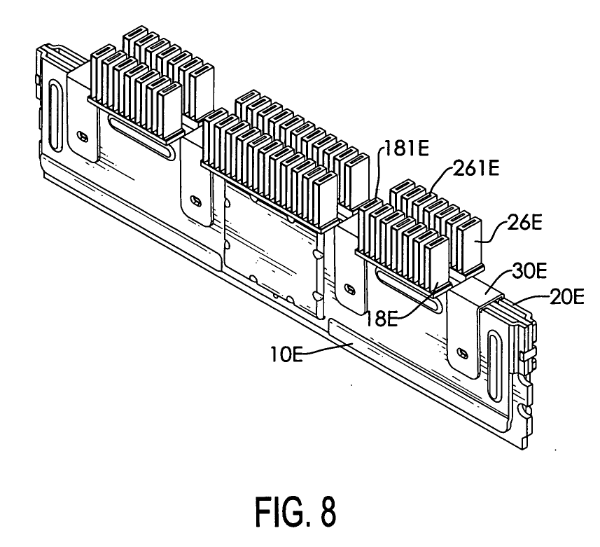

With further reference to FIG. 8, each fin (18E, 26E) has a top and a hole (181E, 261E). The hole (181E, 261E) is formed through the top of the fin (18E, 26E) to increase the heat dissipating efficiency of the fin (18E, 26E)efficiency.

The station bracket (10, 10A, 10B, 10C, 10D, 10E) and the holding bracket (20, 20A, 20B, 20C, 20D, 20E) are able to clamp the electrical device (40) therebetween. The extensions (21) of the holding bracket (20, 20A, 20B, 20C, 20D, 20E) are received into the cutouts (131) of the station bracket (10, 10A, 10B, 10C, 10D, 10E) to hold the electrical device (40) between the station bracket (10, 10A, 10B, 10C, 10D, 10E) and the holding bracket (20, 20A, 20B, 20C, 20D, 20E). The chip (411) of the chip group (41) of the electrical device (40) is received into the recess (11) of the station bracket (10, 10A, 10B, 10C, 10D, 10E). The inner surfaces of the station bracket (10, 10A, 10B, 10C, 10D, 10E) and the holding bracket (20, 20A, 20B, 20C, 20D, 20E) abut against the chip group (41) of the electrical device (40). When the electrical device (40) is in operation, the chip group (41) of the electrical device (40) generates heat. The heat will be transmitted to the station bracket (10, 10A, 10B, 10C, 10D, 10E) and the holding bracket (20, 20A, 20B, 20C, 20D, 20E) and will be efficiently dissipated, so that the chip group (41) of electrical device (40) can keep at a certain working temperature for a long term. The fins (14A, 15B, 16C, 17D, 18E, 22A, 23B, 24C, 25D, 26E ) on the station bracket (10A, 10B, 10C, 10D, 10E) and the holding bracket (20A, 20B, 20C, 20D, 20E) may increase the heat dissipating efficiency of the clamp to efficiently lower the temperature of the chip group (41) of electrical device (40).

Furthermore, the chip (411) of the chip group (41) is received in the recess (11) of the station bracket (10, 10A, 10B, 10C, 10D, 10E). When the chip (411) of the chip group (41) generates heat, the heat generated by the chip (411) can be efficiently dissipated through the holes (12) in the station bracket (10, 10A, 10B, 10C, 10D, 10E) to the circumambient air to lower the temperature of the chip (411) of the chip group (41).

Consequently, the heat dissipating clamp may in accordance with the present invention can fit with different kinds of computers, especially to a computer with a compact size and provide an excellent heat dissipating efficiency to the computer.

Even though numerous characteristics and advantages of the present invention have been set forth in the foregoing description together with details of the structure and function of the invention, the disclosure is illustrative only. Changes may be made in detail especially in matters of shape, size, and arrangement of parts within the principles of the invention to the full extent indicated by the broad general meaning of the terms in which the appended claims are expressed.

What is claimed is:

1. A heat dissipating clamp comprising
a station bracket having
two ends;
an inner surface;
a top; and
a recess formed in the inner surface of the station bracket and having
an edge; and
multiple holes separately formed through the station bracket; and
a holding bracket combined to the station bracket and having
a top;
two ends.

2. The heat dissipating clamp as claimed as claim 1 further having mounted clips separately mounted on the top of the station bracket and the top of the holding bracket to combine the station bracket and the top of the holding bracket together as a clamp.

3. The heat dissipating clamp as claimed as claim 2, wherein the station bracket has two ears each formed on and extending out of one end of the station bracket and having a cutout formed at an edge of the ear; and
the holding bracket has two extensions each formed on and extending out of one end of the holding bracket and received in one of the cutouts in the station bracket.

4. The heat dissipating clamp as claimed as claim 3, wherein the holes of the station bracket are formed through the edge of the recess of the station bracket.

5. The heat dissipating clamp as claimed as claim 4, wherein the mounted clips are U-shaped.

6. The heat dissipating clamp as claimed as claim 5, wherein the station bracket has multiple fins formed on the top of the station bracket and between the mounted clips; and
the holding bracket has multiple fins formed on the top of the holding bracket and between mounted clips.

7. The heat dissipating clamp as claimed as claim 5, wherein the station bracket has multiple fins mounted on the top of the station bracket and between mounted clips; and
the holding bracket has multiple fins mounted on the top of the holding bracket and between mounted clips.

8. The heat dissipating clamp as claimed as claim 7, wherein the fins on the station and holding brackets are triangular-plate-shaped.

9. The heat dissipating clamp as claimed as claim 7, wherein the fins on the station and holding brackets are U-plate-shaped.

10. The heat dissipating clamp as claimed as claim 9, wherein each fin on the station and holding brackets has a top and a hole formed through the top of the fin.
